(19) United States
(12) Patent Application Publication
(10) Pub. No.: US 2015/0243505 A1
(43) Pub. Date: Aug. 27, 2015

(54) METHOD FOR FORMING FIN FIELD EFFECT TRANSISTOR

(71) Applicant: Tsinghua University, Beijing (CN)

(72) Inventors: Jing Wang, Beijing (CN); Lei Xiao, Beijing (CN); Mei Zhao, Beijing (CN); Reneong Liang, Beijing (CN); Jun Xu, Beijing (CN)

(73) Assignee: Tsinghua University, Beijing (CN)

(21) Appl. No.: 14/350,677

(22) PCT Filed: Mar. 21, 2014
(86) PCT No.: PCT/CN2014/073838

§ 371 Date: Apr. 9, 2014

(30) Foreign Application Priority Data
Feb. 25, 2014 (CN) 201410063193.5
Feb. 25, 2014 (CN) 201410063293.8
Feb. 25, 2014 (CN) 201410064598.0

(51) Int. Cl. H01L 21/265; H01L 21/02; H01L 29/66

(52) U.S. Cl. CPC H01L 21/26513; H01L 29/6681; H01L 21/02694; H01L 21/02293

(57) ABSTRACT

A method for forming a FinFET is provided, comprising: providing a substrate; forming a fin structure with a material Ge or GeSi on the substrate; forming a gate stack or a dummy gate on the substrate; defining a first region and a second region in the fin structure; and implanting atoms, molecules, ions or plasmas containing an element Sn into the first region and the second region in the fin structure with the material Ge to form a strained GeSn layer, or implanting atoms, molecules, ions or plasmas containing an element Sn into the first region and the second region in the fin structure with the material GeSi to form a strained GeSnSi layer, or co-implanting atoms, molecules, ions or plasmas containing elements Sn and Si into the first region and the second region in the fin structure with the material GeSi to form a strained GeSnSi layer.

### CROSS-REFERENCE TO RELATED APPLICATIONS

This application claims priority to and benefits of the following applications:

1) Chinese Patent Application Serial No. 201410064598.0, filed with the State Intellectual Property Office of P. R. China on Feb. 25, 2014;

2) Chinese Patent Application Serial No. 201410063193.5, filed with the State Intellectual Property Office of P. R. China on Feb. 25, 2014; and

3) Chinese Patent Application Serial No. 201410063293.8, filed with the State Intellectual Property Office of P. R. China on Feb. 25, 2014.

The entire contents of the above applications are incorporated herein by reference.

### FIELD

The present disclosure relates to a semiconductor design and fabrication field, and more particularly to a method for forming a fin field effect transistor (FinFET).

### BACKGROUND

With an increasingly scaling down of a feature size of MOSFET (metal-oxide-semiconductor field-effect transistor), especially a feature size of a gate length, a short-channel effect becomes more and more serious. In order to effectively suppress the short-channel effect, a FinFET is proposed, a channel of which is thin enough and is only disposed at a place very close to a gate thus eliminating all leakage channels apart from the gate. The FinFET, which may greatly improve a control capability of the gate over the channel and effectively suppress the short-channel effect, has advantages of high drive current, low off-state current, high on-off current ratio, low cost and high transistor density. Moreover, the FinFET devices may be fabricated on a cheap Si or Si-on-insulator (SOI) substrate.

In addition, also with the increasingly scaling down of the feature size of MOSFET, a low carrier mobility of Si has become a primary factor restraining a performance of the devices. In order to solve the problem, a material with higher mobility is adopted as the channel material, for example, Ge or Ge_{1-z}Si_{z} (0<z<1) (GeSi) alloy is adopted as the channel material in PMOSFET, and a group III-V compound semiconductor material is adopted as the channel material in NMOSFETs. A hole mobility of Ge is around four times as great as that of Si, and currently a lot of technical challenges for a Ge channel MOSFET have been overcome. In order to introduce a uniaxis compressive strain in the Ge or GeSi channel of a MOSFET device, a strained Ge₁₋ₓSnₓ (GeSn) alloy may be filled in a source region and a drain region, and the strained GeSn may further introduce the uniaxis compressive strain in the channel, thus greatly improving a performance of the Ge or GeSi channel, especially when a length of the Ge or GeSi channel is on a nanometer scale. A group IV semiconductor material Ge-based Ge₁₋ₓSnₓ (0<x<1) (GeSn) alloy, which is compatible with Ge, is compatible with a silicon CMOS (complementary metal oxide semiconductor) process.

However, it is difficult to directly grow a GeSn alloy with high crystalline quality and high Sn content on a Ge substrate. The reasons are illustrated as follows. Firstly, an equilibrium solid solubility of Sn in Ge is less than 1% (i.e., about 0.3%); secondly, a surface segregation of Sn easily occurs because the surface energy of Sn is smaller than that of Ge; and thirdly, there is a large lattice mismatch (about 14.7%) between Ge and α-Sn. In order to suppress the surface segregation of Sn and increase the content of Sn, a certain amount of Si may be doped during a growth to form a Ge_{1-x-y}SnₓSi_{y} (0<x<1, 0<y<1) (GeSnSi) layer. Because a lattice constant of Si is smaller than that of Ge, but a lattice constant of Sn is larger than that of Ge, a thermal stability of the GeSnSi alloy may be improved by doping Si into it.

It is difficult to fabricate GeSn and GeSnSi since both materials are metastable Ge-based materials. Molecular beam epitaxy (MBE) is conventionally used for growing the GeSn alloy. By using such a method, a GeSn film with high crystal quality may be obtained. Disadvantages (such as expensive equipment, time-consuming fabrication process and high cost) of such a method, however, limit a large scale production. In addition, a uniformity of the film formed by MBE needs to be further improved. Alternatively, chemical vapor deposition (CVD) is also used for growing the GeSn or GeSnSi film but has disadvantages of poor film quality, poor thermal stability and easy segregation of Sn. Moreover, a selective epitaxial growth of the GeSn or GeSnSi films is needed for the FinFET structure. In theory CVD is proper for selectively growing the GeSn or GeSnSi films in the source region and the drain region of the FinFET, however, in practice it is not the case because of disadvantages of poor film quality, immature and complicated process and high cost.

### SUMMARY

Embodiments of the present disclosure seek to solve at least one of the problems existing in the related art to at least some extent.

According to the present disclosure, a method for forming a FinFET is provided. The method comprises: providing a substrate; forming a fin structure with a material Ge or GeSi on the substrate; forming a gate stack or a dummy gate on a top surface and both sides of the fin structure, the gate stack or the dummy gate being oriented transversely to the fin structure; defining a first region and a second region in the fin structure and on both sides of the gate stack or the dummy gate respectively, the first region and the second region being exposed; and implanting atoms, molecules, ions or plasmas containing an element Sn into the first region and the second region in the fin structure with the material Ge to form a strained Ge-based GeSn layer, or implanting atoms, molecules, ions or plasmas containing an element Sn into the first region and the second region in the fin structure with the material GeSi to form a strained Ge-based GeSnSi layer, or co-implanting atoms, molecules, ions or plasmas containing elements Sn and Si into the first region and the second region in the fin structure with the material GeSi to form a strained Ge-based GeSnSi layer, the first region being a source region and the second region being a drain region.

With the method for forming the FinFET, a strained GeSn or GeSnSi source and a strained GeSn or GeSnSi drain with a better crystalline quality are obtained, such that an electrical performance of the FinFET is significantly improved. In addition, the method is simple to implement and low in cost.

In one embodiment, the method further comprises forming a side wall on both sides of the gate stack or the dummy gate before defining the first region and the second region.

In one embodiment, the method further comprises removing the dummy gate and forming a gate stack at a region where the dummy gate is located.

In one embodiment, the fin structure with the material Ge or GeSi is formed by a selective epitaxial growth.

In one embodiment, the fin structure with the material Ge is formed by a photolithography and etching, and the substrate has a surface with a material Ge.

In one embodiment, the fin structure with the material GeSi is formed by a photolithography and etching, and the substrate has a surface with the material GeSi.

In one embodiment, the implanting or the co-implanting comprises an ion implantation.

In one embodiment, the ion implantation comprises a plasma source ion implantation and a plasma immersion ion implantation.

In one embodiment, the implanting or the co-implanting comprises a magnetron sputtering.

In one embodiment, during the magnetron sputtering, a negative bias voltage is applied to the substrate.

In one embodiment, a Sn coating film is formed on the strained Ge-based GeSn layer or the strained Ge-based GeSnSi layer during the magnetron sputtering, in case the atoms, molecules, ions or plasmas containing only the element Sn are implanted; or a Si—Sn coating film is formed on the strained Ge-based GeSnSi layer during the magnetron sputtering, in case the atoms, molecules, ions or plasmas containing the elements Sn and Si are co-implanted.

In one embodiment, the method further comprises removing the Sn coating film or the Si-Sn coating film.

In one embodiment, the method further comprises heating the substrate at a heating temperature ranging from 100° C. to 600° C. during the implanting.

In one embodiment, the heating temperature ranges from 150° C. to 450° C.

In one embodiment, the method further comprises annealing the strained Ge-based GeSn layer or the strained Ge-based GeSnSi layer at an annealing temperature ranging from 100° C. to 600° C. after the implanting.

In one embodiment, the annealing temperature ranges from 150° C. to 450° C.

In one embodiment, a thickness of the strained Ge-based GeSn layer or the strained Ge-based GeSnSi layer ranges from 0.5 nm to 100 nm.

In one embodiment, the thickness of the strained Ge-based GeSn layer or the strained Ge-based GeSnSi layer ranges from 5 nm to 40 nm.

In one embodiment, a Sn content of the strained Ge-based GeSn layer or the strained Ge-based GeSnSi layer is less than 20% by atom percent.

Additional aspects and advantages of embodiments of present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference to the drawings, in which:

FIGS. 1-4b are schematic views of intermediate statuses of a FinFET formed in steps of a method for forming a FinFET by a gate-first process according to an embodiment of the present disclosure;

FIG. 5 is a flow chart of a method for forming a FinFET with a GeSn source and a GeSn drain by the gate-first process according to a first embodiment of the present disclosure;

FIG. 6 is an X-ray diffraction (224) reciprocal space map of a GeSn layer according to an embodiment of the present disclosure;

FIG. 7 is a flow chart of a method for forming a FinFET with a GeSnSi source and a GeSnSi drain by the gate-first process according to a second embodiment of the present disclosure;

FIG. 8 is a flow chart of a method for forming a FinFET with a GeSnSi source and a GeSnSi drain by the gate-first process according to a third embodiment of the present disclosure;

FIGS. 9-13b are schematic views of intermediate statuses of a FinFET formed in steps of a method for forming a FinFET by a gate-last process according to an embodiment of the present disclosure;

FIG. 14 is a flow chart of a method for forming a FinFET with a GeSn source and a GeSn drain by the gate-last process according to a fourth embodiment of the present disclosure;

FIG. 15 is a flow chart of a method for forming a FinFET with a GeSnSi source and a GeSnSi drain by the gate-last process according to a fifth embodiment of the present disclosure; and

FIG. 16 is a flow chart of a method for forming a FinFET with a GeSnSi source and a GeSnSi drain by the gate-last process according to a sixth embodiment of the present disclosure.

### DETAILED DESCRIPTION

Reference will be made in detail to embodiments of the present disclosure. The embodiments described herein with reference to drawings are explanatory, illustrative, and used to generally understand the present disclosure. The embodiments shall not be construed to limit the present disclosure. The same or similar elements and the elements having same or similar functions are denoted by like reference numerals throughout the descriptions.

In the specification, unless specified or limited otherwise, relative terms such as “central”, “longitudinal”, “lateral”, “front”, “rear”, “right”, “left”, “inner”, “outer”, “lower”, “upper”, “horizontal”, “vertical”, “above”, “below”, “up”, “top”, “bottom” as well as derivative thereof (e.g., “horizontally”, “downwardly”, “upwardly”, etc.) should be construed to refer to the orientation as then described or as shown in the drawings under discussion. These relative terms are for convenience of description and do not require that the present disclosure be constructed or operated in a particular orientation.

A method for forming a FinFET is provided according to embodiments of the present disclosure. The method comprises: providing a substrate; forming a fin structure with a material Ge or GeSi on the substrate; forming a gate stack or a dummy gate on a top surface and both sides of the fin structure, the gate stack or the dummy gate being oriented transversely to the fin structure; defining a first region and a second region in the fin structure and on both sides of the gate stack or the dummy gate respectively, the first region and the second region being exposed; and implanting atoms, molecules, ions or plasmas containing an element Sn into the first region and the second region in the fin structure with the material Ge to form a strained GeSn layer, or implanting atoms, molecules, ions or plasmas containing an element Sn into the first region and the second region in the fin structure with the material GeSi to form a strained GeSnSi layer, or co-implanting atoms, molecules, ions or plasmas containing elements Sn and Si into the first region and the second region in the fin structure with the material GeSi to form a strained GeSnSi layer, the first region being a source region and the second region being a drain region.

With the method for forming the FinFET according to embodiments of the present disclosure, a surface modification is performed for the source region and the drain region in the original fin structure with the material Ge or GeSi by using an implantation process, that is, the atoms, molecules, ions or plasmas containing at least the element Sn are implanted into the source region and the drain region in the original fin structure with the material Ge or GeSi. By controlling a temperature and an implanting dose, the implanted element Sn may not be diffused obviously, such that the Sn atoms in lattice may not be aggregated to form a Sn precipitate, thus keeping a GeSn or GeSnSi alloy in its metastable state without precipitation and surface segregation. In this way, a strained GeSn or GeSnSi source and a strained GeSn or GeSnSi drain with a better crystalline quality are obtained, such that an electrical performance of the FinFET is significantly improved. In addition, the method is simple to implement and low in cost.

In terms of conventional methods for forming a FinFET, a MBE method has disadvantages of expensive equipment, ultra-high vacuum, time-consuming fabrication process and high cost, and a CVD method has disadvantages of poor film quality, poor thermal stability, high cost and easy segregation of Sn at a high growth temperature. In addition, it is difficult to form a high quality Ge-based film in a selective region by both the MBE method and the CVD method, that is, neither the MBE method nor the CVD method is proper for selectively growing the high quality Ge-based film. In addition, since a nonplanar Ge-based film is required for forming the FinFET, a uniformity of the nonplanar film formed by MBE is not good.

The method for forming the FinFET according to embodiments of the present disclosure may use a gate-first process or a gate-last process, both of which will be described in detail as follows.

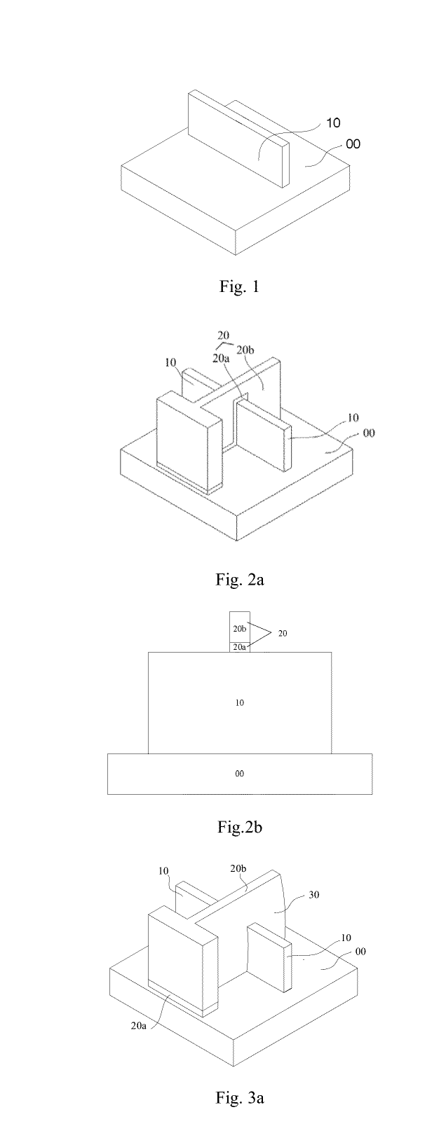

The method for forming the FinFET using the gate-first process will be illustrated below with reference to FIGS. 1-4b. The method may comprise following steps.

At first step, a substrate 00 is provided. Specifically, the substrate 00 may be a semiconductor substrate, including, but not limited to, a Si (silicon) substrate, a Ge (germanium) substrate, a Si-on-insulator substrate, a Ge-on-insulator substrate, a Si substrate with a Ge surface, a GeSi-on-insulator substrate, a Si substrate with a GeSi surface, and a Ge substrate with a GeSi surface.

At second step, a fin structure 10 with a material Ge or GeSi is formed on the substrate 00, as shown in FIG. 1.

At third step, a gate stack 20 is formed on a top surface and both sides of the fin structure 10, in which the gate stack 20 is oriented transversely to the fin structure 10, as shown in FIGS. 2a and 2b, in which FIG. 2a is a schematic perspective view of the device, and FIG. 2b is a cross-sectional view of the device shown in FIG. 2a in a length direction of a channel of the FinFET. Specifically, a gate dielectric material and a gate metal material are deposited on the fin structure sequentially, and then a patterned gate stack 20 comprising a gate dielectric layer 20a and a gate metal 20b is formed by photolithography and etching.

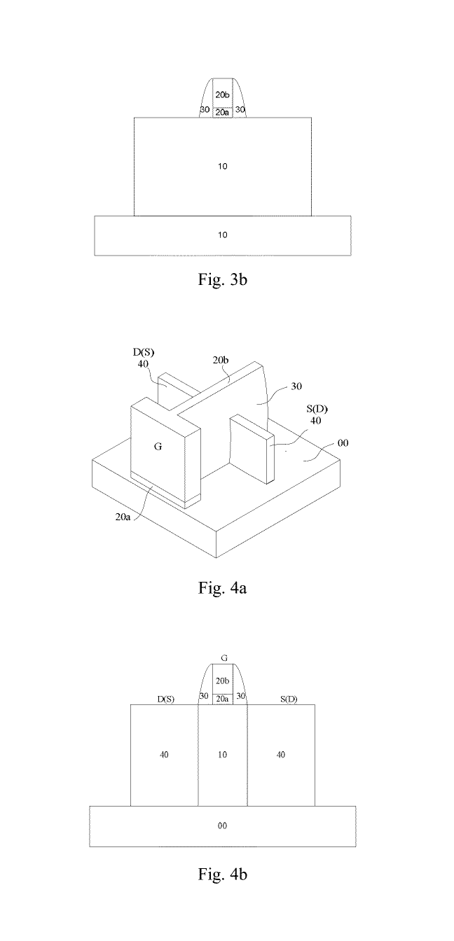

At fourth step, a first region and a second region are defined in the fin structure 10 and on both sides of the gate stack 20 respectively, in which the first region and the second region are exposed, as shown in FIGS. 3a and 3b, in which FIG. 3a is a schematic perspective view of the device, and FIG. 3b is a cross-sectional view of the device shown in FIG. 3a in the length direction of the channel of the FinFET. The first region and the second region are preset for a source region and a drain region respectively. In one embodiment, a side wall 30 may be further formed on both sides of the gate stack 20 by photolithography and dry etching before defining the first region and the second region. The side wall 30 may reduce a leakage current of a device.

At fifth step, atoms, molecules, ions or plasmas containing an element Sn or containing elements Sn and Si are implanted into the first region and the second region to form a strained GeSn layer 40 or a strained GeSnSi layer 40, as shown in FIGS. 4a and 4b, in which FIG. 4a is a schematic perspective view of the device, and FIG. 4b is a cross-sectional view of the device shown in FIG. 4a in the length direction of the channel of the FinFET. In one embodiment, surfaces of the exposed first region and the exposed second region may be implanted to form the strained layer 40. In another embodiment, the whole exposed first region and the whole exposed second region may be implanted to form the strained layer 40. The strained layer 40 serves as the source and the drain of the FinFET.

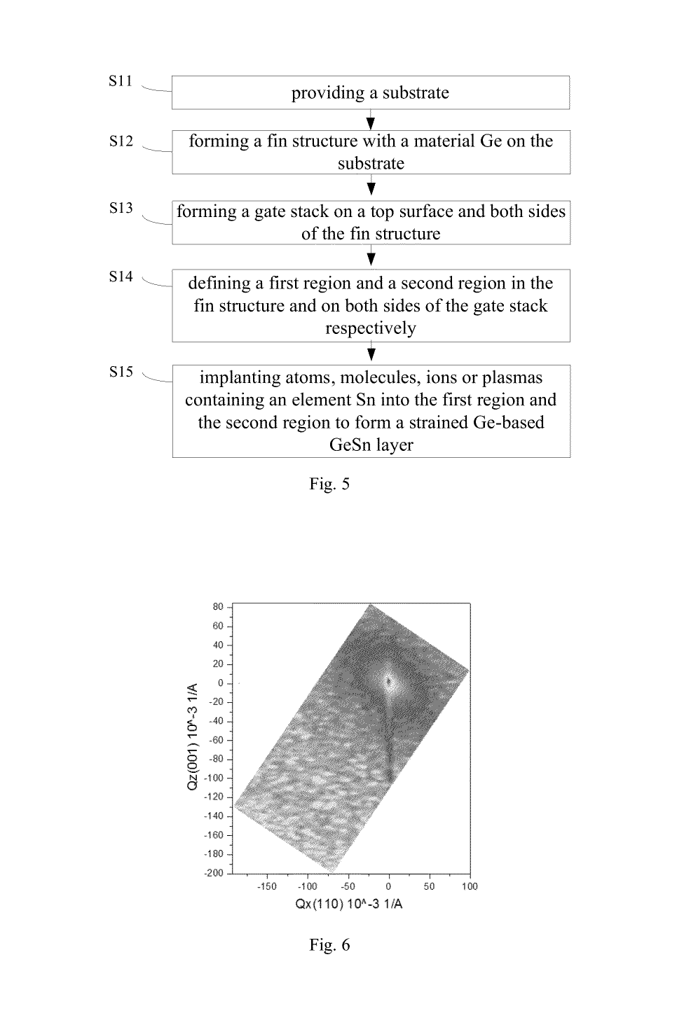

FIG. 5 is a flow chart of the method for forming the FinFET with a GeSn source and a GeSn drain by the gate-first process according to a first embodiment of the present disclosure. As shown in FIG. 5, the method may comprise following steps.

At step S11, a substrate is provided.

At step S12, a fin structure with a material Ge is formed on the substrate.

In an exemplary example, the fin structure with the material Ge may be formed by a selective epitaxial growth. In this case, since the material Ge of the fin structure is not an inherent material of the substrate but is epitaxially grown on the substrate later, the substrate may be selected from a broad range of substrates, including, but not limited to, a Si substrate, a Ge substrate, a Si-on-insulator substrate, a Ge-on-insulator substrate, and a Si substrate with a Ge surface.

In another exemplary example, the fin structure with the material Ge may be formed by a photolithography and etching. In this case, since the material Ge of the fin structure is the inherent material of the substrate, the substrate may be selected from a relatively narrow range of substrates, including, but not limited to, a Ge substrate, a Ge-on-insulator substrate, and a Si substrate with a Ge surface, that is, the substrate should at least have a Ge surface.

At step S13, a gate stack is formed on a top surface and both sides of the fin structure, in which the gate stack is oriented transversely to the fin structure.

At step S14, a first region and a second region are defined in the fin structure and on both sides of the gate stack respectively, in which the first region and the second region are exposed.

At step S15, atoms, molecules, ions or plasmas containing an element Sn are implanted into the first region and the second region to form a strained GeSn layer.

A specific embodiment will be illustrated below for a better understanding of the present disclosure.

Firstly, a Si substrate is provided and rinsed sequentially by acetone, absolute ethyl alcohol, deionized water and hydrofluoric acid.

Secondly, a fin structure with a material Ge is formed on the Si substrate by a selective epitaxial growth. Specifically, a silicon nitride mask is deposited on the Si substrate, and an opening is formed in the mask by photolithography and etching, and the fin structure with the material Ge is formed in the opening by the selective epitaxial growth. A thickness of the fin structure is controlled to be larger than that of the mask.

Thirdly, a gate dielectric material HfO₂ and a gate metal material TaN/TiAl/TiN are deposited on the substrate sequentially, and then a patterned gate stack HfO₂/TaN/TiAl/TiN is formed on the Si substrate and is oriented transversely to the fin structure by photolithography and etching.

Fourthly, a side wall material (such as Si₃N₄) is deposited on the substrate, and then a patterned side wall is formed on both sides of the gate stack by photolithography and dry etching.

Fifthly, a first region and a second region are defined in the fin structure and on both sides of the gate stack respectively, in which the first region and the second region are exposed.

Finally, plasmas containing an element Sn are implanted into exposed parts of the fin structure (i.e., the first region and the second region) by a plasma immersion ion implantation. An implanting voltage is 10-25 KeV, and an implanting dose is about 5×10¹⁶/cm². During the implanting, the Si substrate is heated at a temperature ranging from 100° C. to 200° C. After the implanting is completed, a strained GeSn layer with a thickness of 15-30 nm is formed on surfaces of the exposed parts of the fin structure. The Sn content of the strained GeSn layer is about 8%. In this way, a GeSn source and a GeSn drain are formed in the first region and the second region respectively. The strained GeSn layer may be annealed at a temperature ranging from 200° C. to 300° C. after the implanting so as to further improve the strained GeSn layer. Alternatively, the strained GeSn layer may be formed by a magnetron sputtering. During the magnetron sputtering, a vacuum degree is less than 10⁻⁴ Pa, and the Si substrate is heated at a temperature ranging from 100° C. to 200° C. Firstly, a strained GeSn layer is formed on the surfaces of the exposed parts of the fin structure, and then a Sn coating layer is formed on the strained GeSn layer. The strained GeSn layer may be annealed at a temperature ranging from 100° C. to 200° C. after the implanting so as to further improve the strained GeSn layer. Finally, the Sn coating layer is removed to expose the strained GeSn layer by means of a diluted hydrochloric acid (such as with a concentration of 5%).

It can be seen from an X-ray diffraction (224) reciprocal space map of the GeSn layer, vertically downward extended reciprocal space points in the map are attributed to the strained GeSn layer, as shown in FIG. 6. The result further indicates that the GeSn layer formed by this method is strained.

In this way, a FinFET device with a strained GeSn source and a strained GeSn drain is obtained.

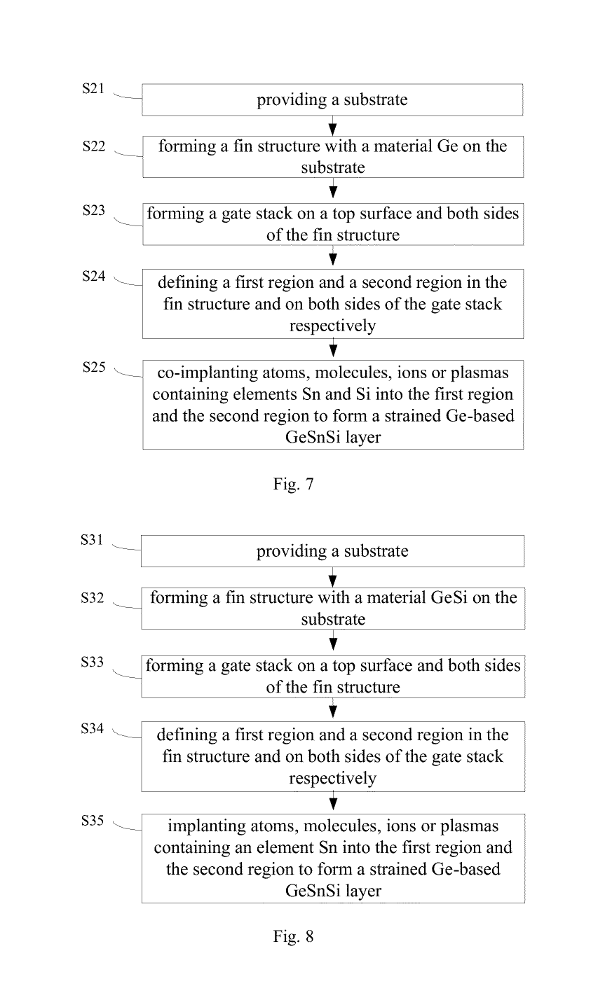

FIG. 7 is a flow chart of the method for forming the FinFET with a GeSnSi source and a GeSnSi drain by the gate-first process according to a second embodiment of the present disclosure. As shown in FIG. 7, the method may comprise following steps.

At step S21, a substrate is provided.

At step S22, a fin structure with a material Ge is formed on the substrate.

In an exemplary example, the fin structure with the material Ge may be formed by a selective epitaxial growth. In this case, since the material Ge of the fin structure is not an inherent material of the substrate but is epitaxially grown on the substrate later, the substrate may be selected from a broad range of substrates, including, but not limited to, a Si substrate, a Ge substrate, a Si-on-insulator substrate, a Ge-on-insulator substrate, and a Si substrate with a Ge surface.

In another exemplary example, the fin structure with the material Ge may be formed by a photolithography and etching. In this case, since the material Ge of the fin structure is the inherent material of the substrate, the substrate may be selected from a relatively narrow range of substrates, including, but not limited to, a Ge substrate, a Ge-on-insulator substrate, and a Si substrate with a Ge surface, that is, the substrate should at least have a Ge surface.

At step S23, a gate stack is formed on a top surface and both sides of the fin structure, in which the gate stack is oriented transversely to the fin structure.

At step S24, a first region and a second region are defined in the fin structure and on both sides of the gate stack respectively, in which the first region and the second region are exposed.

At step S25, atoms, molecules, ions or plasmas containing elements Sn and Si are implanted into the first region and the second region to form a strained GeSnSi layer.

A specific embodiment will be illustrated below for a better understanding of the present disclosure.

Firstly, a Si substrate is provided and rinsed sequentially by acetone, absolute ethyl alcohol, deionized water and hydrofluoric acid.

Secondly, a fin structure with a material Ge is formed on the Si substrate by a selective epitaxial growth. Specifically, a silicon nitride mask is deposited on the Si substrate, and an opening is formed in the mask by photolithography and etching, and the fin structure with the material Ge is formed in the opening by the selective epitaxial growth. A thickness of the fin structure is controlled to be larger than that of the mask.

Thirdly, a gate dielectric material HfO₂ and a gate metal material TaN/TiAl/TiN are deposited on the substrate sequentially, and then a patterned gate stack HfO₂/TaN/TiAl/TiN is formed on the Si substrate and is oriented transversely to the fin structure by photolithography and etching.

Fourthly, a side wall material (such as Si₃N₄) is deposited on the substrate, and then a patterned side wall is formed on both sides of the gate stack by photolithography and dry etching.

Fifthly, a first region and a second region are defined in the fin structure and on both sides of the gate stack respectively, in which the first region and the second region are exposed.

Finally, plasmas containing elements Sn and Si are implanted into exposed parts of the fin structure (i.e., the first region and the second region) by a plasma immersion ion implantation. An implanting voltage is 10-25 KeV, and an implanting dose of Si is about 1×10¹⁷/cm² and an implanting dose of Sn is about 8×10¹⁶/cm^{2.} During the implanting, the Si substrate is heated at a temperature ranging from 100° C. to 200° C. After the implanting is completed, a strained GeSnSi layer with a thickness of 15-30 nm is formed on surfaces of the exposed parts of the fin structure. The Sn content of the strained GeSnSi layer is about 15%. In this way, a GeSnSi source and a GeSnSi drain are formed in the first region and the second region respectively. The strained GeSnSi layer may be annealed at a temperature ranging from 200° C. to 300° C. after the implanting so as to further improve the strained GeSnSi layer.

In this way, a FinFET device with a strained GeSnSi source and a strained GeSnSi drain is obtained.

FIG. 8 is a flow chart of the method for forming the FinFET with a GeSnSi source and a GeSnSi drain by the gate-first process according to a third embodiment of the present disclosure. As shown in FIG. 8, the method may comprise following steps.

At step S31, a substrate is provided.

At step S32, a fin structure with a material GeSi is formed on the substrate.

In an exemplary example, the fin structure with the material GeSi may be formed by a selective epitaxial growth. In this case, since the material GeSi of the fin structure is not an inherent material of the substrate but is epitaxially grown on the substrate later, the substrate may be selected from a broad range of substrates, including, but not limited to, a Si substrate, a Ge substrate, a Si-on-insulator substrate, a Ge-on-insulator substrate, a GeSi-on-insulator substrate, a Si substrate with a GeSi surface, and a Ge substrate with a GeSi surface.

In another exemplary example, the fin structure with the material GeSi may be formed by a photolithography and etching. In this case, since the material GeSi of the fin structure is the inherent material of the substrate, the substrate may be selected from a relatively narrow range of substrates, including, but not limited to, a GeSi-on-insulator substrate, a Si substrate with a GeSi surface, and a Ge substrate with a GeSi surface, that is, the substrate should at least have a GeSi surface.

At step S33, a gate stack is formed on a top surface and both sides of the fin structure, in which the gate stack is oriented transversely to the fin structure.

At step S34, a first region and a second region are defined in the fin structure and on both sides of the gate stack respectively, in which the first region and the second region are exposed.

At step S35, atoms, molecules, ions or plasmas containing an element Sn are implanted into the first region and the second region to form a strained GeSnSi layer.

A specific embodiment will be illustrated below for a better understanding of the present disclosure.

Firstly, a Si substrate is provided and rinsed sequentially by acetone, absolute ethyl alcohol, deionized water and hydrofluoric acid.

Secondly, a fin structure with a material GeSi is formed on the Si substrate by a selective epitaxial growth. Specifically, a silicon nitride mask is deposited on the Si substrate, and an opening is formed in the mask by photolithography and etching, and the fin structure with the material GeSi is formed in the opening by the selective epitaxial growth. A thickness of the fin structure is controlled to be larger than that of the mask.

Thirdly, a gate dielectric material HfO₂ and a gate metal material TaN/TiAl/TiN are deposited on the substrate sequentially, and then a patterned gate stack HfO₂/TaN/TiAl/TiN is formed on the Si substrate and is oriented transversely to the fin structure by photolithography and etching.

Fourthly, a side wall material (such as Si₃N₄) is deposited on the substrate, and then a patterned side wall is formed on both sides of the gate stack by photolithography and dry etching.

Fifthly, a first region and a second region are defined in the fin structure and on both sides of the gate stack respectively, in which the first region and the second region are exposed.

Finally, plasmas containing an element Sn are implanted into exposed parts of the fin structure (i.e., the first region and the second region) by a plasma immersion ion implantation. An implanting voltage is 10-25 KeV, and an implanting dose is about 5×10¹⁶/cm². During the implanting, the Si substrate is heated at a temperature ranging from 100° C. to 200° C. After the implanting is completed, a strained GeSnSi layer with a thickness of 15-30 nm is formed on surfaces of the exposed parts of the fin structure. The Sn content of the strained GeSnSi layer is about 8%. In this way, a GeSnSi source and a GeSnSi drain are formed in the first region and the second region respectively. The strained GeSnSi layer may be annealed at a temperature ranging from 200° C. to 300° C. after the implanting so as to further improve the strained GeSnSi layer.

In this way, a FinFET device with a strained GeSnSi source and a strained GeSnSi drain is obtained.

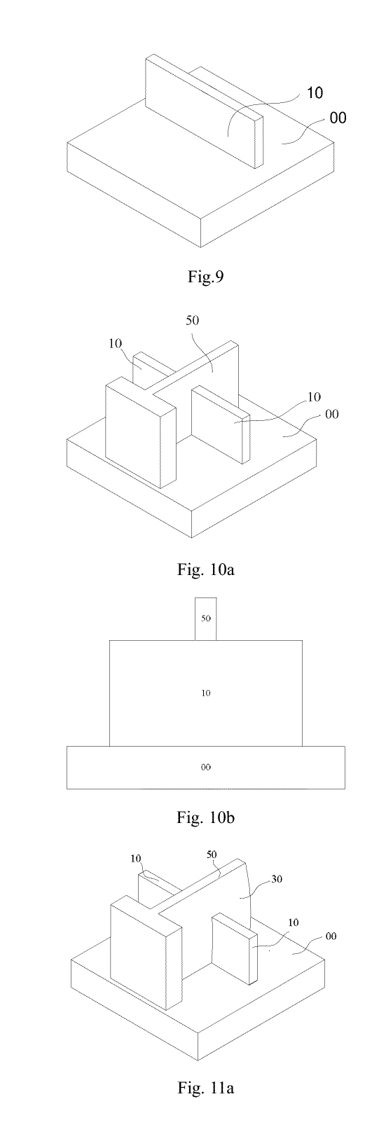

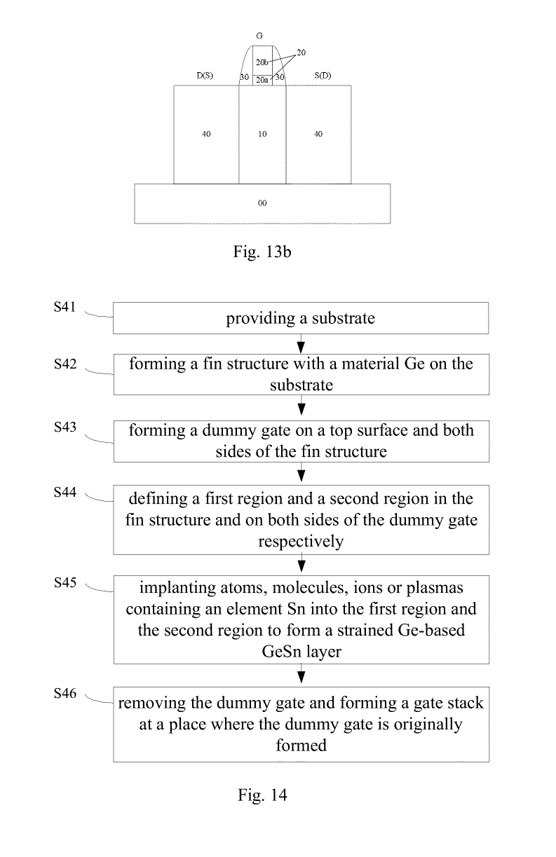

The method for forming the FinFET using the gate-last process will be illustrated below with reference to FIGS. 9-13b. The method may comprise following steps.

At first step, a substrate 00 is provided. Specifically, the substrate 00 may be a semiconductor substrate, including, but not limited to, a Si (silicon) substrate, a Ge (germanium) substrate, a Si-on-insulator substrate, a Ge-on-insulator substrate, a Si substrate with a Ge surface, a GeSi-on-insulator substrate, a Si substrate with a GeSi surface, and a Ge substrate with a GeSi surface.

At second step, a fin structure 10 with a material Ge or GeSi is formed on the substrate 00, as shown in FIG. 9.

At third step, a dummy gate 50 is formed on a top surface and both sides of the fin structure 10, in which the dummy gate 50 is oriented transversely to the fin structure 10, as shown in FIGS. 10a and 10b, in which FIG. 10a is a schematic perspective view of the device, and FIG. 10b is a cross-sectional view of the device shown in FIG. 10a in a length direction of a channel of the FinFET.

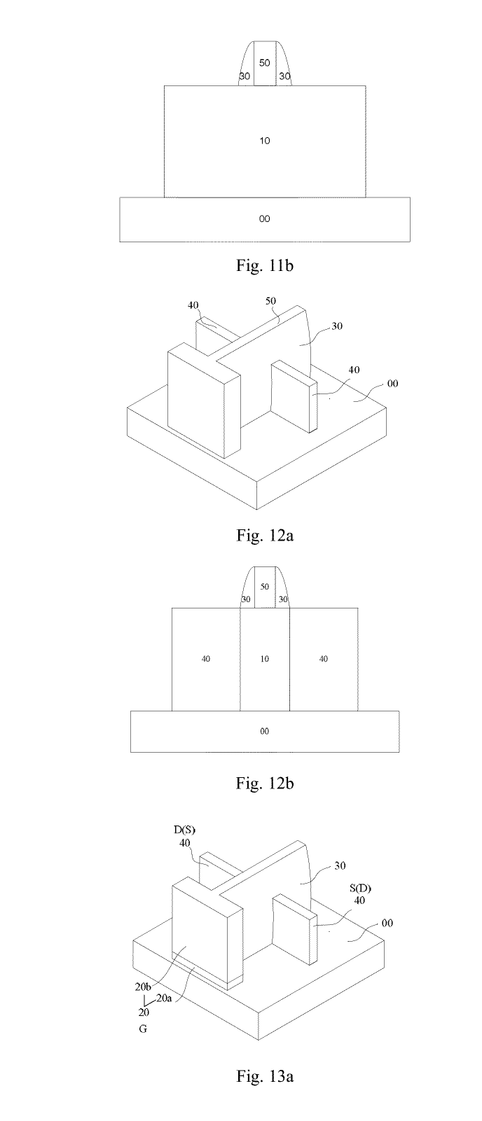

At fourth step, a first region and a second region are defined in the fin structure 10 and on both sides of the dummy gate 50 respectively, in which the first region and the second region are exposed, as shown in FIGS. 11a and 11b, in which FIG. 11a is a schematic perspective view of the device, and FIG. 11b is a cross-sectional view of the device shown in FIG. 11a in the length direction of the channel of the FinFET. The first region and the second region are preset for a source region and a drain region respectively. In one embodiment, a side wall 30 may be further formed on both sides of the dummy gate 50 by photolithography and dry etching before defining the first region and the second region. The side wall 30 is usually made of a dielectric material different from a material of the dummy gate 50. The side wall 30 may reduce a leakage current of a device.

At fifth step, atoms, molecules, ions or plasmas containing an element Sn or containing elements Sn and Si are implanted into the first region and the second region to form a strained GeSn layer 40 or a strained GeSnSi layer 40, as shown in FIGS. 12a and 12b, in which FIG. 12a is a schematic perspective view of the device, and FIG. 12b is a cross-sectional view of the device shown in FIG. 12a in the length direction of the channel of the FinFET. In one embodiment, surfaces of the exposed first region and the exposed second region may be implanted to form the strained layer 40. In another embodiment, the whole exposed first region and the whole exposed second region may be implanted to form the strained layer 40. The strained layer 40 serves as the source and the drain of the FinFET.

At sixth step, the dummy gate 50 is removed and a gate stack 20 is formed at a place where the dummy gate 50 is originally formed. Specifically, the dummy gate 50 may be removed by a wet etching or a combination of the wet etching and the dry etching, a gate dielectric material and a gate metal material are deposited on the substrate 00 sequentially, and then a patterned gate stack 20 comprising a gate dielectric layer 20a and a gate metal 20b is formed by photolithography and etching.

FIG. 14 is a flow chart of the method for forming the FinFET with a GeSn source and a GeSn drain by the gate-last process according to a fourth embodiment of the present disclosure. As shown in FIG. 14, the method may comprise following steps.

At step S41, a substrate is provided.

At step S42, a fin structure with a material Ge is formed on the substrate.

In an exemplary example, the fin structure with the material Ge may be formed by a selective epitaxial growth. In this case, since the material Ge of the fin structure is not an inherent material of the substrate but is epitaxially grown on the substrate later, the substrate may be selected from a broad range of substrates, including, but not limited to, a Si substrate, a Ge substrate, a Si-on-insulator substrate, a Ge-on-insulator substrate, and a Si substrate with a Ge surface.

In another exemplary example, the fin structure with the material Ge may be formed by a photolithography and etching. In this case, since the material Ge of the fin structure is the inherent material of the substrate, the substrate may be selected from a relatively narrow range of substrates, including, but not limited to, a Ge substrate, a Ge-on-insulator substrate, and a Si substrate with a Ge surface, that is, the substrate should at least have a Ge surface.

At step S43, a dummy gate is formed on a top surface and both sides of the fin structure, in which the dummy gate is oriented transversely to the fin structure.

At step S44, a first region and a second region are defined in the fin structure and on both sides of the dummy gate respectively, in which the first region and the second region are exposed.

At step S45, atoms, molecules, ions or plasmas containing an element Sn are implanted into the first region and the second region to form a strained GeSn layer.

At step S46, the dummy gate is removed and a gate stack is formed at a place where the dummy gate is originally formed.

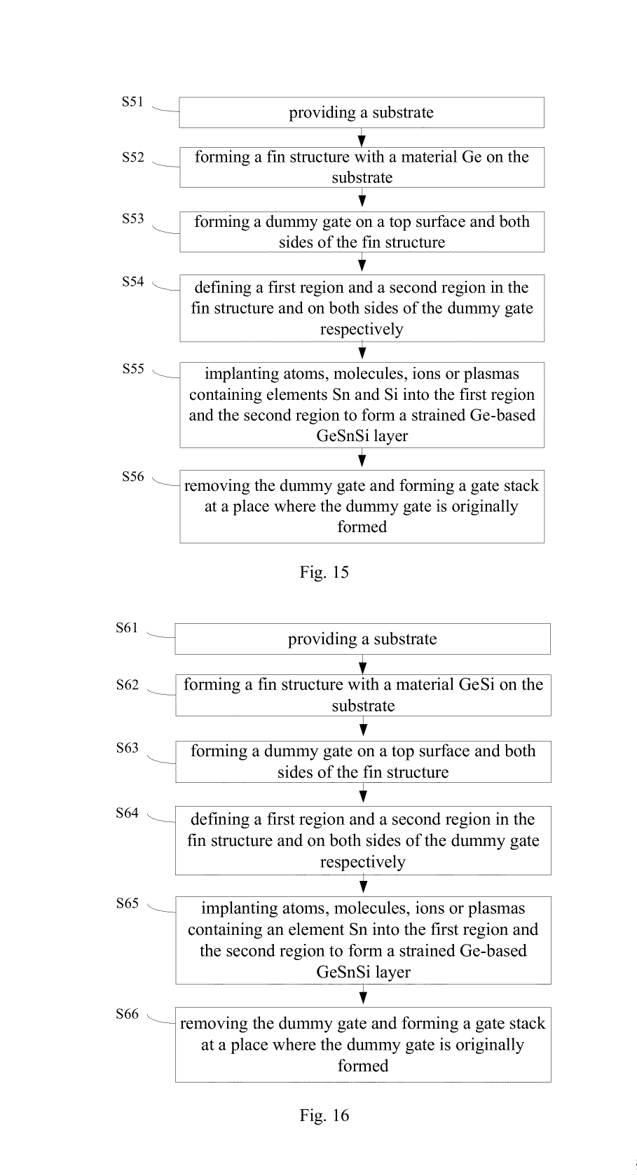

FIG. 15 is a flow chart of the method for forming the FinFET with a GeSnSi source and a GeSnSi drain by the gate-last process according to a fifth embodiment of the present disclosure. As shown in FIG. 15, the method may comprise following steps.

At step S51, a substrate is provided.

At step S52, a fin structure with a material Ge is formed on the substrate.

In an exemplary example, the fin structure with the material Ge may be formed by a selective epitaxial growth. In this case, since the material Ge of the fin structure is not an inherent material of the substrate but is epitaxially grown on the substrate later, the substrate may be selected from a broad range of substrates, including, but not limited to, a Si substrate, a Ge substrate, a Si-on-insulator substrate, a Ge-on-insulator substrate, and a Si substrate with a Ge surface.

In another exemplary example, the fin structure with the material Ge may be formed by a photolithography and etching. In this case, since the material Ge of the fin structure is the inherent material of the substrate, the substrate may be selected from a relatively narrow range of substrates, including, but not limited to, a Ge substrate, a Ge-on-insulator substrate, and a Si substrate with a Ge surface, that is, the substrate should at least have a Ge surface.

At step S53, a dummy gate is formed on a top surface and both sides of the fin structure, in which the dummy gate is oriented transversely to the fin structure.

At step S54, a first region and a second region are defined in the fin structure and on both sides of the dummy gate respectively, in which the first region and the second region are exposed.

At step S55, atoms, molecules, ions or plasmas containing elements Sn and Si are implanted into the first region and the second region to form a strained GeSnSi layer.

At step S56, the dummy gate is removed and a gate stack is formed at a place where the dummy gate is originally formed.

FIG. 16 is a flow chart of the method for forming the FinFET with a GeSnSi source and a GeSnSi drain by the gate-last process according to a sixth embodiment of the present disclosure. As shown in FIG. 16, the method may comprise following steps.

At step S61, a substrate is provided.

At step S62, a fin structure with a material GeSi is formed on the substrate.

In an exemplary example, the fin structure with the material GeSi may be formed by a selective epitaxial growth. In this case, since the material GeSi of the fin structure is not an inherent material of the substrate but is epitaxially grown on the substrate later, the substrate may be selected from a broad range of substrates, including, but not limited to, a Si substrate, a Ge substrate, a Si-on-insulator substrate, a Ge-on-insulator substrate, a GeSi-on-insulator substrate, a Si substrate with a GeSi surface, and a Ge substrate with a GeSi surface.

In another exemplary example, the fin structure with the material GeSi may be formed by a photolithography and etching. In this case, since the material GeSi of the fin structure is the inherent material of the substrate, the substrate may be selected from a relatively narrow range of substrates, including, but not limited to, a GeSi-on-insulator substrate, a Si substrate with a GeSi surface, and a Ge substrate with a GeSi surface, that is, the substrate should at least have a GeSi surface.

At step S63, a dummy gate is formed on a top surface and both sides of the fin structure, in which the dummy gate is oriented transversely to the fin structure.

At step S64, a first region and a second region are defined in the fin structure and on both sides of the dummy gate respectively, in which the first region and the second region are exposed.

At step S65, atoms, molecules, ions or plasmas containing an element Sn are implanted into the first region and the second region to form a strained GeSnSi layer.

At step S66, the dummy gate is removed and a gate stack is formed at a place where the dummy gate is originally formed.

With the method for forming the FinFET, a strained GeSn or GeSnSi source and a strained GeSn or GeSnSi drain with a better crystalline quality are obtained, such that an electrical performance of the FinFET is significantly improved. In addition, the method is simple to implement and low in cost.

It should be noted that, for both the gate-first process and the gate-last process, a surface of the fin structure may be implanted to form the strained GeSn layer or the strained GeSnSi layer, or the whole fin structure may be implanted to form the strained GeSn layer or the strained GeSnSi layer. If a thick layer is required for the source and the drain of the FinFET, only the ions or plasmas containing the element Sn or containing elements Sn and Si which have higher energy may be implanted into the fin structure to arrive at an intended depth. If a thin layer is required for the source and the drain of the FinFET, the atoms, molecules, ions or plasmas containing the element Sn or containing elements Sn and Si may be implanted into the fin structure.

In an exemplary example, the implantation may be implemented by an ion implantation, that is, an ion beam (including ions and/or plasmas) with certain energy and containing the specific element(s) (e.g., Sn, or a combination of Sn and Si) is injected into the fin structure with the material Ge or GeSi, such that a part of the fin structure or the whole fin structure is converted into a GeSn alloy or a GeSnSi alloy (i.e., the GeSn layer or the GeSnSi layer). An implanting depth depends on the energy of the ion beam, that is, the higher the energy of the ion beam is, the larger the implanting depth is, and thus the thicker the GeSn layer or the GeSnSi layer is. In one embodiment, a thickness of the GeSn layer or the GeSnSi layer may range from 0.5 nm to 100 nm. During the implanting, a varying voltage may be used to vary the energy of the ion beam, such that the element Sn may be distributed uniformly within a certain range. Specifically, the ion implantation may comprise a plasma source ion implantation and a plasma immersion ion implantation, i.e., a plasma-based ion implantation (PBII). For the PBII, the fin structure with the material Ge or GeSi is immersed in the plasmas containing specific element(s), positive plasmas containing the specific element(s) are accelerated by an electric field, injected to the surface of the fin structure and finally implanted into the fin structure. It is easy to achieve a high implanting dose by the PBII, for example, a Sn content of the GeSn layer or the GeSnSi layer may range from 1% to 20% by atom percent. In this way, a production efficiency is improved and the cost is lowered. Since the PBII is less affected by a morphology of a substrate surface, it is particularly preferred for nonplanar structures (such as the fin structure) to ensure a uniform implantation, such that a uniform GeSn or GeSnSi film may be formed in the whole source region and the whole drain region, thus greatly improving the electrical performance of the channel.

In another exemplary example, the implantation may be implemented by a magnetron sputtering. During the magnetron sputtering, Ar ions are accelerated by an electric field to reach a target containing specific element(s) (e.g., Sn, or a combination of Sn and Si), and bombard the target with high energy to make the target generate a sputtering. Sputtered particles contain a major portion of atoms and a minor portion of ions. By adjusting a process parameter (such as a voltage of the electric field, or a vacuum degree), the sputtered particles may have higher energy and are injected to the fin structure at a higher speed. A portion of the sputtered particles may be implanted into the fin structure to form the metastable Ge-based alloy. Alternatively, during the magnetron sputtering, a negative bias voltage (for example, ranging from −40 to −120V) is applied to the substrate, which may provide the portion of the sputtered particles with higher energy so as to implant these sputtered particles into a larger depth (such as a few nanometers) of the fin structure.

It should be noted that, because a great number of particles are sputtered, a Sn coating film or a Si—Sn coating film may be further formed on the GeSn layer or the GeSnSi layer. Therefore, the method further comprises removing the Sn coating film or the Si—Sn coating film, for example, by means of a rinse solution with a high selective etching ratio between GeSn (or GeSnSi) and Sn. Such a rinse solution comprises: diluted hydrochloric acid, diluted sulphuric acid and diluted nitric acid. After rinsing, the thickness of the GeSn layer or the GeSnSi layer may range from 0.5 nm to 20 nm, preferably, from 0.5 nm to 10 nm.

In one example, an ion beam sputtering is also used to implant Sn atoms or Sn and Si atoms into the fin structure. Compared with the magnetron sputtering, during the ion beam sputtering, an ion beam is introduced via an ion optical system so as to avoid an influence of a plasma ambiance on the sputtering process. By adjusting the energy of the ion beam, most sputtered particles contain only a single Sn atom and Sn atoms are not liable to aggregation, thus improving the quality and the thermal stability of the GeSn layer or the GeSnSi layer.

In one embodiment, the substrate may be heated during the implanting. A heating temperature may range from 100° C. to 600° C., preferably from 150° C. to 450° C. The film formed at this heating temperature will have a better crystalline quality. A lattice damage resulting from the implantation may not be repaired at an over low heating temperature (e.g., less than 100° C.), such that the quality of the GeSn layer or the GeSnSi layer may be poor. Sn atoms in the GeSn layer or the GeSnSi layer may be seriously diffused at an over high heating temperature (e.g., higher than 600° C.), such that the Sn atoms may be segregated from the GeSn layer or the GeSnSi layer since an equilibrium solid solubility of Sn in Ge or GeSi is very low, e.g., only 0.3% by atom percent in an equilibrium state.

In one embodiment, the GeSn layer or the GeSnSi layer may be annealed after the implanting so as to further improve the crystalline quality of the GeSn layer or the GeSnSi layer. An annealing temperature may range from 100° C. to 600° C., preferably from 150° C. to 450° C. The lattice damage resulting from the implantation may not be repaired at an over low annealing temperature (e.g., less than 100° C.), such that the quality of the GeSn layer or the GeSnSi layer may be poor. Sn in the GeSn layer or the GeSnSi layer may be seriously diffused at an over high annealing temperature (e.g., higher than 600° C.), such that Sn atoms may be segregated from the GeSn layer or the GeSnSi layer since the equilibrium solid solubility of Sn in Ge or GeSi is very low. It should be pointed out that, for the gate-first process, the gate dielectric is not capable of withstanding a high temperature above 450° C., and thus the heating temperature and the annealing temperature should be below 450° C.

In one embodiment, a thickness of the strained GeSn layer or the GeSnSi layer may range from 0.5 nm to 100 nm, preferably from 5 nm to 40 nm. The Sn content of the strained GeSn layer or the strained GeSnSi layer is less than 20% by atom percent.

For the fully strained GeSn layer, the higher the Sn content is, the larger the strain degree is, and correspondingly the thickness of the strained GeSn layer should be less than its critical thickness to keep it fully strained, that is, the higher the Sn content is, the smaller the critical thickness is. Here, the critical thickness is determined by a condition that strain energy of the strained GeSn layer is equal to a minimum dislocation formation energy. For example, when the Sn content of the strained GeSn layer is 10%, the strain degree of the fully strained GeSn layer is about 1.5%, and the critical thickness of the strained GeSn layer is about 30 nm, that is, a thickness of the GeSn source and the GeSn drain of the FinFET should be equal to or less than 30 nm. Also for example, when the Sn content of the strained GeSn layer is 5%, the strain degree thereof is about 0.8%, and the critical thickness thereof may be over 100 nm, that is, the thickness of the GeSn source and the drain of the FinFET may be 100 nm while the GeSn layer remains fully strained.

For the fully strained GeSnSi layer, the higher the Sn content is, the larger the strain degree is, and correspondingly the thickness of the strained GeSnSi layer should be less than its critical thickness to keep it fully strained, that is, the higher the Sn content is, the smaller the critical thickness is. For example, when the Si content of the strained GeSnSi layer is 20% and the Sn content of the strained GeSnSi layer is 15%, the strain degree of the fully strained GeSnSi layer is about 1.5%, and the critical thickness of the strained GeSnSi layer is about 30 nm, that is, a thickness of the GeSnSi source and the GeSnSi drain of the FinFET should be equal to or less than 30 nm. Also for example, when the Si content of the strained GeSnSi layer is 20% and the Sn content of the strained GeSnSi layer is 10%, the strain degree thereof is about 0.8%, and the critical thickness thereof may be over 100 nm, that is, the thickness of the GeSnSi source and the GeSnSi drain of the FinFET may be 100 nm while the GeSnSi layer remains fully strained.

It should be noted that, the heating temperature and the annealing temperature need to match with material properties of the strained GeSn layer or the GeSnSi layer. For example, because the Sn content of the strained GeSn layer in a common FinFET usually ranges from 3% to 8% by atom percent, and the strained GeSn layer with a Sn content of 8% is stable at a temperature below 450° C., the heating temperature and the annealing temperature should not exceed 450° C. Also for example, because the Sn content of the strained GeSnSi layer in a common FinFET usually ranges from 10% to 15% by atom percent, by adding the element Si, the strained GeSnSi layer with a Sn content of 10%-15% is basically stable at a temperature below 450° C., the heating temperature and the annealing temperature should not exceed 450° C.

A FinFET is further provided according to embodiments of the present disclosure. The FinFET comprises: a substrate; a fin channel with a material Ge or GeSi on the substrate; a gate stack on the substrate, the gate stack being oriented transversely to the fin channel; and a source region and a drain region with a material GeSn or GeSnSi on both sides of the gate stack respectively. It should be noted that the FinFET with a GeSn or GeSnSi source and a GeSn or GeSnSi drain may be formed by a method, including, but not limited to, any of the methods described above. With the FinFET according to embodiments of the present disclosure, the GeSn or GeSnSi source and the GeSn or GeSnSi drain have advantages of high mobility and better crystalline quality. The FinFET device has advantages of improved electrical performance and low cost.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that the above embodiments cannot be construed to limit the present disclosure, and changes, alternatives, and modifications can be made in the embodiments without departing from spirit, principles and scope of the present disclosure.

What is claimed is:

1. A method for forming a fin field effect transistor, comprising:
providing a substrate;
forming a fin structure with a material Ge or GeSi on the substrate;
forming a gate stack or a dummy gate on a top surface and both sides of the fin structure, the gate stack or the dummy gate being oriented transversely to the fin structure;
defining a first region and a second region in the fin structure and on both sides of the gate stack or the dummy gate respectively, the first region and the second region being exposed; and
implanting atoms, molecules, ions or plasmas containing an element Sn into the first region and the second region in the fin structure with the material Ge to form a strained Ge-based GeSn layer, or
implanting atoms, molecules, ions or plasmas containing an element Sn into the first region and the second region in the fin structure with the material GeSi to form a strained Ge-based GeSnSi layer, or
co-implanting atoms, molecules, ions or plasmas containing elements Sn and Si into the first region and the second region in the fin structure with the material GeSi to form a strained Ge-based GeSnSi layer,
the first region being a source region and the second region being a drain region.

2. The method according to claim 1, further comprising forming a side wall on both sides of the gate stack or the dummy gate before defining the first region and the second region.

3. The method according to claim 1, further comprising removing the dummy gate and forming a gate stack at a region where the dummy gate is located.

4. The method according to claim 1, wherein the fin structure with the material Ge or GeSi is formed by a selective epitaxial growth.

5. The method according to claim 1, wherein the fin structure with the material Ge is formed by a photolithography and etching, and the substrate has a surface with a material Ge.

6. The method according to claim 1, wherein the fin structure with the material GeSi is formed by a photolithography and etching, and the substrate has a surface with the material GeSi.

7. The method according to claim 1, wherein the implanting or the co-implanting comprises an ion implantation.

8. The method according to claim 7, wherein the ion implantation comprises a plasma source ion implantation and a plasma immersion ion implantation.

9. The method according to claim 1, wherein the implanting or the co-implanting comprises a magnetron sputtering.

10. The method according to claim 9, wherein during the magnetron sputtering, a negative bias voltage is applied to the substrate.

11. The method according to claim 9, wherein
a Sn coating film is formed on the strained Ge-based GeSn layer or the strained Ge-based GeSnSi layer during the magnetron sputtering, if the atoms, molecules, ions or plasmas containing only the element Sn are implanted; or
a Si—Sn coating film is formed on the strained Ge-based GeSnSi layer during the magnetron sputtering, if the atoms, molecules, ions or plasmas containing the elements Sn and Si are co-implanted.

12. The method according to claim 11, further comprising removing the Sn coating film or the Si—Sn coating film.

13. The method according to claim 1, further comprising heating the substrate at a heating temperature ranging from 100° C. to 600° C. during the implanting.

14. The method according to claim 13, wherein the heating temperature ranges from 150° C. to 450° C.

15. The method according to claim 1, further comprising annealing the strained Ge-based GeSn layer or the strained Ge-based GeSnSi layer at an annealing temperature ranging from 100° C. to 600° C. after the implanting.

16. The method according to claim 15, wherein the annealing temperature ranges from 150° C. to 450° C.

17. The method according to claim 1, wherein a thickness of the strained Ge-based GeSn layer or the strained Ge-based GeSnSi layer ranges from 0.5 nm to 100 nm.

18. The method according to claim 17, wherein the thickness of the strained Ge-based GeSn layer or the strained Ge-based GeSnSi layer ranges from 5 nm to 40 nm.

19. The method according to claim 1, wherein a Sn content of the strained Ge-based GeSn layer or the strained Ge-based GeSnSi layer is less than 20% by atom percent.
